(19) United States
(12) Patent Application Publication
(10) Pub. No.: US 2025/0163321 A1
(43) Pub. Date: May 22, 2025

(54) QUANTUM DOT MATERIAL AND PREPARATION METHOD THEREFOR, AND LIGHT-EMITTING DIODE

(71) Applicant: TCL TECHNOLOGY GROUP CORPORATION, Huizhou, Guangdong (CN)

(72) Inventors: Panning HUANG, Huizhou, Guangdong (CN); Zizhe LU; Zijian HUANG, Huizhou, Guangdong (CN)

(73) Assignee: TCL TECHNOLOGY GROUP CORPORATION, Huizhou, Guangdong (CN)

(21) Appl. No.: 18/842,046

(22) PCT Filed: Oct. 26, 2022
(86) PCT No.: PCT/CN2022/127781

§ 371 Date: Aug. 28, 2024

(30) Foreign Application Priority Data
Feb. 28, 2022 (CN) 202210186331.3

(51) Int. Cl. C09K 11/88; H10K 50/115; H10K 50/81; H10K 50/82

(52) U.S. Cl. CPC C09K 11/883; H10K 50/115; H10K 50/81; H10K 50/82

(57) ABSTRACT

A quantum dot material and preparation method therefor, and a light-emitting diode, and a quantum dot light-emitting diode. The quantum dot material includes quantum dots and ligands each of which is bonded to a surface of one of the quantum dots. Each of the ligands has a structural formula as following:

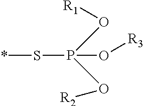

The quantum dot material has relatively higher stability, a relatively small number of surface defects, and a relatively low Fermi level. When quantum dot light-emitting layer is fabricated by the quantum dot material, the hole transport rate can be effectively increased, and the light-emitting efficiency and service life of the light-emitting diode can be improved.

This application claims priority of the Chinese patent disclosure with the Chinese Patent Disclosure No. 202210186331.3, filed in the China National Intellectual Property Administration on Feb. 28, 2022, and entitled “QUANTUM DOT MATERIAL AND PREPARATION METHOD THEREFOR, COMPOSITION, LIGHT-EMITTING DIODE, AND DISPLAY DEVICE”, which is incorporated herein by reference in its entirety.

### TECHNICAL FIELD

The present disclosure relates to the field of display technologies, and more particularly, to a quantum dot material, a preparation method for the quantum dot material, and a light-emitting diode.

### BACKGROUND

Quantum dots are special materials that are limited to the order of nanometers in three dimensions. This remarkable quantum confinement effect makes quantum dots have many unique nano-properties, such as continuously adjustable emission wavelength, narrow emission wavelength, wide absorption spectrum, high luminous intensity, long fluorescence life, and good biocompatibility. These characteristics make quantum dots have a wide application prospect in flat panel display, solid-state lighting, photovoltaic solar energy, biomarker, and other fields. Especially in flat panel display applications, quantum dot light-emitting diode (QLED) based on quantum dot materials have shown great potential in display image quality, device performance, and manufacturing cost by leveraging the characteristics and advantages of quantum dot nanomaterials.

In recent years, although the performance of QLED devices in each aspects has been continuously improved, and the service life and performance of QLED devices prepared from red quantum dots and green quantum dots have reached commercial standards. However, the service life and performance of QLED devices prepared from blue quantum dots are still lower, and is far from reaching commercial application, which greatly hinders the development and application of quantum dot electroluminescence display technology.

The existing QLED devices prepared from blue quantum dots have a short service life.

### Technical Solutions

Therefore, the present disclosure provides a quantum dot material, a preparation method for the quantum dot material, and a light-emitting diode.

Embodiments of the present disclosure provide a quantum dot material including quantum dots and ligands each of which is bonded to a surface of one of the quantum dots, each of the ligand has a structural formula as following:

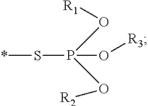

where R₁, R₂, and R₃ are independently selected from a substituted or unsubstituted linear alkyl group having 1 to 20 carbon atoms, or a substituted or unsubstituted branched alkyl group having 3 to 20 carbon atoms;
* represents an attachment site to which the quantum dots bind.

Alternatively, the quantum dot material is included of the quantum dots and the ligands each of which is bonded to one of the surface of the quantum dots.

Alternatively, R₁, R₂, and R₃ are all selected from methyl.

Alternatively, in the quantum dot material, a mass ratio of the quantum dots to the ligands is (0.5˜2):1.

Alternatively, an emission wavelength of each of the quantum dots ranges from 465 nm to 480 nm.

Alternatively, the quantum dots are selected from single structure quantum dots, and the single structure quantum dots are selected from one or more of CdZnSeS, CdS, ZnS, ZnSeS, CdSeS, CdZnS, ZnTeS, CdTeS, ZnCdTeS, CuInS₂, and AgInS₂.

Alternatively, the quantum dots are selected from core-shell structured quantum dots, and a material of an outermost shell layer of each of the quantum dots is selected from one or more of CdZnSeS, CdS, ZnS, ZnSeS, CdSeS, CdZnS, ZnTeS, CdTeS, ZnCdTeS, CuInS₂, and AgInS₂; a material of a quantum dot core of each of the quantum dots and materials of shell layers of each of the quantum dots except the outermost shell layer are independently selected from one or more of a Group II-VI compound, a Group III-V compound, and a Group I-III-VI compound, the Group II-VI compound is selected from one or more of CdSe, CdS, CdTe, ZnSe, ZnS, CdTe, ZnTe, CdZnS, ZnCdSe, CdZnTe, ZnSeS, ZnSeTe, ZnTeS, CdSeS, CdSeTe, CdTeS, ZnCdSeTe, and ZnCdSTe; the Group III-V compound is selected from one or more of InP, InAs, GaP, GaAs, GaSb, AlN, AlP, InAsP, InNP, InNSb, GaAlNP, and InAlNP; the Group I-III-VI compound is selected from one or more of CuInS₂, CuInSe₂, and AgInS₂.

Alternatively, the quantum dots are selected from one or more of a blue core-shell quantum dot CdZnSeS/ZnS or a blue core-shell quantum dot CdSeS/ZnS.

Correspondingly, the embodiments of the present disclosure further provide a preparation method for a quantum dot material, which includes following steps:
dispersing quantum dots in a dispersant to obtain a quantum dot dispersion liquid; and
mixing compounds A to the quantum dot dispersion liquid, and heating to obtain a quantum dot material;
wherein each of the compounds A has a structural formula as following:

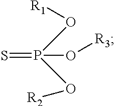

where R₁, R₂, and R₃ are independently selected from a substituted or unsubstituted linear alkyl group having 1 to 20 carbon atoms, or a substituted or unsubstituted branched alkyl group having 3 to 20 carbon atoms.

Alternatively, the quantum dot material includes quantum dots and ligands each of which is bonded to a surface of one of the quantum dot, each of the ligands has a structural formula as following:

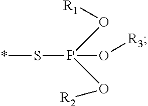

where * represents an attachment site to which the quantum dots bind.

Alternatively, a concentration of the quantum dot dispersion liquid ranges from 10 mg/mL to 30 mg/mL.

Alternatively, a mass ratio of the compounds A to the quantum dots is (2˜9):(1˜2).

Alternatively, the heating includes: blowing an inert gas at a first temperature for a first time, and then reacting at a second temperature for a second time.

Alternatively, the first temperature ranges from 80° C. to 100° C., and the first time ranges from 30 minutes to 60 minutes.

Alternatively, the second temperature ranges from 200° C. to 250° C., and the second time ranges from 1 hours to 2 hours.

Alternatively, before the heating, the method further includes: mixing an acid to the quantum dot dispersion liquid to adjust the pH of the solution system to 6˜7.

Alternatively, the acid is selected from one or more of phosphoric acid, nitric acid, and sulfuric acid.

Correspondingly, the embodiments of the present disclosure further provide a light-emitting diode including a bottom electrode, a light-emitting layer, and a top electrode stacked sequentially, wherein the light-emitting layer is made of the quantum dot material.

Alternatively, the anode is selected from a doped metal oxide electrode, a composite electrode, a graphene electrode, a carbon nanotube electrode, a metal elemental electrode, or an alloy electrode, the doped metal oxide electrode is made of a material selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS; and the cathode is made of a material selected from one or more of Ag, Mg, Al, Au, Pt, Ca, and Ba.

In the present disclosure, the quantum dot material includes the quantum dot and the ligand bonded to the surface of the quantum dot, so that the quantum dot material has relatively higher stability, a relatively small number of surface defects, and a relatively low Fermi level. When quantum dot light-emitting layer is fabricated by the quantum dot material, the energy level between the quantum dot light-emitting layer and the hole transport layer can be more matched, the contact potential difference formed at the interface between the quantum dot light-emitting layer and the hole transport layer can be reduced, thereby the transmission difficulty of holes from the hole transport layer to the quantum dot light-emitting layer can be reduced, so that the hole transport rate can be effectively increased, the electron-hole transmission of the light-emitting diode can be more balanced, and the light-emitting efficiency and service life of the light-emitting diode can be improved.

### BRIEF DESCRIPTION OF FIGURES

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a flowchart of a preparation method for a quantum dot material according to an embodiment of the present disclosure;

FIG. 2 is a schematic diagram of a quantum dot material produced by a reaction between a quantum dot and a compound A according to an embodiment of the present application;

FIG. 3 is a structural schematic diagram of a quantum dot light-emitting diode according to an embodiment of the present disclosure;

FIG. 4 is a structural schematic diagram of another quantum dot light-emitting diode according to an embodiment of the present disclosure;

FIG. 5 is a structural schematic diagram of another quantum dot light-emitting diode according to an embodiment of the present disclosure.

### EMBODIMENTS OF THE PRESENT DISCLOSURE

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure.

In the present disclosure, unless stated to the contrary, the location words used such as “upper” and “lower” usually refer to the upper and lower in the actual use or working state of the device, specifically the drawing direction in the accompanying figures; while “inner” and “outer” are for the outline of the device. In addition, in the description of the present disclosure, the term “comprising/including” means “comprising/including but not limited to”. The terms first, second, third, etc. are used for indication only, and do not impose numerical requirements or establish order.

In the present disclosure, the terms “one or more” refer to one or more of the listed items, and “a plurality of/multiple” refers to any combination of two or more of these items, including any combination of a single item (species) or a plurality of items (species). For example, “at least one of a, b, or c” or “at least one of a, b, and c” may mean a, b, c, a-b (that is, a and b), a-c, b-c, or a-b-c, wherein a, b, and c may be a single item or a plurality of items, respectively.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

Embodiments of the present disclosure provide a quantum dot material, the quantum dot material includes quantum dots and ligands each of which is bonded to a surface of one of the quantum dots. Each of the ligands has a structural formula as following:

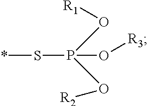

where R₁, R₂, and R₃ are independently selected from a substituted or unsubstituted linear alkyl group having 1 to 20 carbon atoms, or a substituted or unsubstituted branched alkyl group having 3 to 20 carbon atoms; * represents an attachment site to which the quantum dots bind.

In the quantum dot material, a mass ratio of the quantum dots to the ligands is (0.5˜2):1. Within the range, the ligands can coat the surface of the quantum dots well.

A surface of each of the quantum dots has a metal cation, and the S (sulfur) of each of the ligands is connected to the metal cation by a coordination bond. In other words, each of the ligands is connected to a surface of one of the quantum dots by the S (shown in FIG. 2).

The S of each of the ligands is connected to the metal cation on the surface of one of the quantum dots by a coordination bond. The S has a strong binding force with the metal cation, so that the ligand has a strong binding force with the quantum dot, and it is not easy to fall off from the surface of the quantum dot, thereby effectively improving the stability of the quantum dot material. In addition, the S of each of the ligands coordinates with the metal cation on the surface of a quantum dot, which can effectively passivate surface defects of the quantum dot, so that the quantum dot material has better light-emitting efficiency and service life.

In at least one embodiment, R₁, R₂, and R₃ are all selected from methyl. Thereby, each of the ligands has a short chain length and is a short chain ligand. Compared with the long chain ligand such as oleyamine and oleic acid conventionally used for surface modification of the quantum dot, a steric hindrance between molecules of ligands described in the present disclosure and a steric hindrance between the ligand described in the present disclosure and the surface of the quantum dot are small, so that the ligands can cover the surface of the quantum dot to a large extent, thereby effectively improving the dispersion performance and stability of the quantum dot material, reducing or even avoiding agglomeration of the quantum dot material, so that the quantum dot material has better film-forming properties, thereby improving the light-emitting efficiency and service life of the light-emitting diode. The steric hindrance between molecules of ligands and the steric hindrance between the ligand and the surface of the quantum dot are small, which can further greatly reduce the steric hindrance of a quantum dot light-emitting layer made of the quantum dot material, thereby reducing an internal resistance of the quantum dot light-emitting layer, and further reducing a turned-on voltage of the light-emitting diode including the quantum dot light-emitting layer.

Furthermore, the phosphate ion of each of the ligands of the present disclosure can perform P-type doping on the quantum dot, thus to make the quantum dots becomes a shallow acceptor level, thereby lowering the Fermi level of the quantum dots, and causing the quantum dot material to have a lower Fermi level. Thereby, when a quantum dot light-emitting layer is fabricated by the quantum dot material, an energy level between the quantum dot light-emitting layer and a hole transport layer can be more matched, and a contact potential difference (CPD) formed at an interface between the quantum dot light-emitting layer and the hole transport layer can be reduced, thereby the transmission difficulty of holes from the hole transport layer to the quantum dot light-emitting layer can be reduced, so that the hole transport rate can be effectively increased, the electron-hole transmission of the light-emitting diode can be more balanced, and the light-emitting efficiency and service life of the light-emitting diode can be improved.

An emission wavelength of each of the quantum dots ranges from 465 nm to 480 nm, that is, the quantum dots are blue fluorescent quantum dots. In other words, the quantum dots are blue quantum dots or blue light-emitting quantum dots. The quantum dot material is used in blue light-emitting diode to improve the service life of the existing blue light emitting diode.

In some embodiments, the quantum dots are single structure quantum dots. The single structure quantum dots may be selected from, but not limited to, one or more of CdZnSeS, CdS, ZnS, ZnSeS, CdSeS, CdZnS, ZnTeS, CdTeS, ZnCdTeS, CuInS₂, and AgInS₂.

In other embodiments, the quantum dots are core-shell structured quantum dots. Each of the core-shell structured quantum dots includes a quantum dot core and at least one shell layer covering the quantum dot core.

A material of an outermost shell layer of each of the quantum dots may be selected from, but not limited to, one or more of CdZnSeS, CdS, ZnS, ZnSeS, CdSeS, CdZnS, ZnTeS, CdTeS, ZnCdTeS, CuInS₂, and AgInS₂.

A material of the quantum dot core and materials of shell layers except the outermost shell layer may be independently selected from, but not limited to, one or more of a Group II-VI compound, a Group III-V compound, and a Group I-III-VI compound. For example, the Group II-VI compound may be selected from, but not limited to, one or more of CdSe, CdS, CdTe, ZnSe, ZnS, CdTe, ZnTe, CdZnS, ZnCdSe, CdZnTe, ZnSeS, ZnSeTe, ZnTeS, CdSeS, CdSeTe, CdTeS, ZnCdSeTe, and ZnCdSTe. The Group III-V compound may be selected from, but not limited to, one or more of InP, InAs, GaP, GaAs, GaSb, AlN, AlP, InAsP, InNP, InNSb, GaAlNP, and InAlNP. The Group I-III-VI compound may be selected from, but not limited to, one or more of CuInS₂, CuInSe₂, and AgInS₂.

In at least one embodiment, the core-shell structured quantum dots are blue core-shell quantum dots CdZnSeS/ZnS or blue core-shell quantum dots CdSeS/ZnS.

In the present disclosure, the quantum dot material includes the quantum dots and the ligands each of which is bonded to a surface of one of the quantum dots, so that the quantum dot material has relatively higher stability, a relatively small number of surface defects, and a lower Fermi level. When a quantum dot light-emitting layer is fabricated by the quantum dot material, the energy level between the quantum dot light-emitting layer and the hole transport layer can be more matched, the contact potential difference formed at the interface between the quantum dot light-emitting layer and the hole transport layer can be reduced, thereby the transmission difficulty of holes from the hole transport layer to the quantum dot light-emitting layer can be reduced, so that the hole transport rate can be effectively increased, thereby, the electron-hole transmission of the light-emitting diode can be more balanced, and the light-emitting efficiency and service life of the light-emitting diode can be improved.

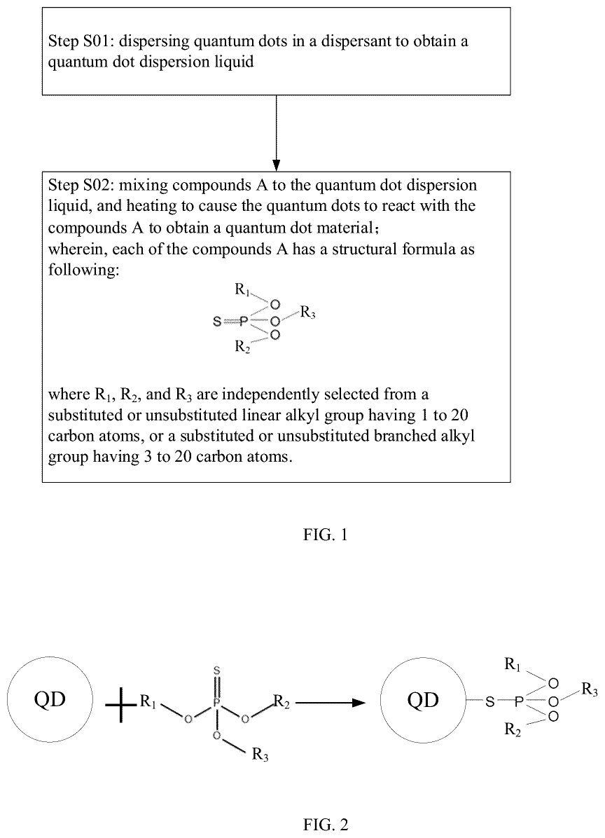

Referring to FIG. 1 to FIG. 2, embodiments of the present disclosure further provide a preparation method for a quantum dot material, which includes following steps:
Step S01: dispersing quantum dots in a dispersant to obtain a quantum dot dispersion liquid;
Step S02: mixing compounds A to the quantum dot dispersion liquid, and heating to cause the quantum dots to react with the compounds A to obtain a quantum dot material.

Each of the compounds A has a structural formula as following:

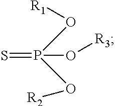

Where R₁, R₂, and R₃ are independently selected from a substituted or unsubstituted linear alkyl group having 1 to 20 carbon atoms, or a substituted or unsubstituted branched alkyl group having 3 to 20 carbon atoms.

In at least one embodiment, R₁, R₂, and R₃ are all selected from methyl. In this case, the compound A is trimethyl thiophosphate.

The structural formula of the trimethyl thiophosphate is as follows:

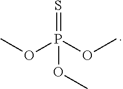

The surface of each of the quantum dots has bare metal cations, and while heating, the S of each of the compounds A and a bare metal cation on the surface of a quantum dot are connected together by a coordination bond, or the compounds A replace original ligands on the surface of a quantum dot, thereby the S of a compound A and one metal cation on the surface of a quantum dot are connected together by a coordination bond.

Moreover, the original ligands on the surface of the quantum dot may be selected from, but not limited to, one or more of an acid ligand, a thiol ligand, an amine ligand, a (oxy)phosphine ligand, a phospholipid, a soft phospholipid, and a polyvinylpyridine. For example, the acid ligand may be selected from, but not limited to, one or more of decanoic acid, undecylenic acid, myristanoic acid, oleic acid, stearic acid. The thiol ligand may be selected from, but not limited to, one or more of octadecyl mercaptan, dodecyl mercaptan, octadecyl mercaptan. The amine ligand may be selected from, but not limited to, one or more of oleylamine, octadecylamine, octaamine. The (oxy)phosphine ligand may be selected from, but not limited to, one or more of trioctylphosphine and trioctylphosphine oxide.

In the step S01:

The quantum dots can be referred to the above description, and will not be described herein.

The dispersant may be a polar solvent or a non-polar solvent known in the art for dispersing quantum dots. The polar solvent may be selected from, but not limited to, one or more of methanol, ethanol, isopropanol, acetone, ethyl acetate, acetonitrile. The non-polar solvent may be selected from, but not limited to, one or more of n-octane, benzene, toluene, cyclohexane, hexane, cyclooctane, and octane.

A concentration of the quantum dot dispersion liquid ranges from 10 mg/mL to 30 mg/mL. Within the range, the reaction between the quantum dot and the compound A is facilitated.

In the step S02:

A mass ratio of the compounds A to the quantum dots is (2˜9):(1˜2). Within the range, the compounds A can be sufficiently reacted with the quantum dots.

In some embodiments, the heating includes: blowing an inert gas at a first temperature for a first time, and then reacting at a second temperature for a second time.

The first temperature ranges from 80° C. to 100° C., and the first time ranges from 30 minutes to 60 minutes. Within the range of the temperature and the range of time, it is possible to ensure that most of oxygen in the solution system is cleaned up to avoid oxygen attacking the quantum dots.

Moreover, the inert gas may be selected from, but not limited to, nitrogen, argon, helium, and the like.

The second temperature ranges from 200° C. to 250° C., and the second time ranges from 1 hours to 2 hours. Within the range: in one aspect, it is advantageous for the S of the compounds A to connect to the metal cation exposed on the surface of the quantum dots by a coordination bond, thus to form the ligands described hereinbefore; in another aspect, it is advantageous to P-type doping the quantum dots by the phosphate ion of the ligands.

In some embodiments, before the heating reaction, the method further includes: mixing an acid to the quantum dot dispersion liquid to adjust the pH of the solution system to 6˜7. Thereby, a weakly acidic environment can be provided, which facilitates the reaction between the compounds A and the quantum dots.

The acid may be selected from, but not limited to, one or more of phosphoric acid, nitric acid, and sulfuric acid. In at least one embodiment, the acid is selected from phosphoric acid. Furthermore, the phosphoric acid is selected from a phosphoric acid having a mass concentration ranging from 5% to 10%.

It can be understood that, an order of mixing compounds A to the quantum dot dispersion liquid and mixing an acid to the quantum dot dispersion liquid is not limited.

In some embodiments, in the step S02, after the heating reaction further includes a step of post-treatment the solution system to extract the quantum dot material.

It can be understood that, the post-treatment may be a method known in the art for separating liquids from solids, such as sedimentation, filtration, or the like. In at least one embodiment, the post-treatment is a sedimentation treatment. The sedimentation treatment may be achieved by adding a precipitating agent. The precipitating agent may be selected from the polar solvent or the non-polar solvent described above. It can be understood that, the polarity of the precipitating agent is opposite to the polarity of the dispersant. For example, when the dispersant is selected from the polar solvent, the precipitating agent is selected from the non-polar solvent; and when the dispersant is selected from the non-polar solvent, the precipitating agent is selected from the polar solvent.

It can be understood that, after the step S02, the method further includes: cleaning the quantum dot material, and drying the quantum dot material, so that impurities physically adsorbed on the surface of the quantum dot material are removed to obtain a higher purity quantum dot material.

Embodiments of the present disclosure further provide a composition including the quantum dot material and an organic solvent.

The organic solvent is a conventional organic solvent for dispersing quantum dot materials. For example, the organic solvent may be selected from, but not limited to, one or more of methanol, ethanol, isopropanol, acetone, ethyl acetate, acetonitrile, n-octane, benzene, toluene, cyclohexane, hexane, cyclooctane, and octane.

In the composition, a concentration of the quantum dot material ranges from 10 mg/mL to 30 mg/mL. If the concentration is too low, it may result in a non-dense film after film formation, thereby lead to issues such as leakage current when using the film as a light-emitting layer. If the concentration is too high, there may be problems such as aggregation of the composition and the formation of an excessively thick film.

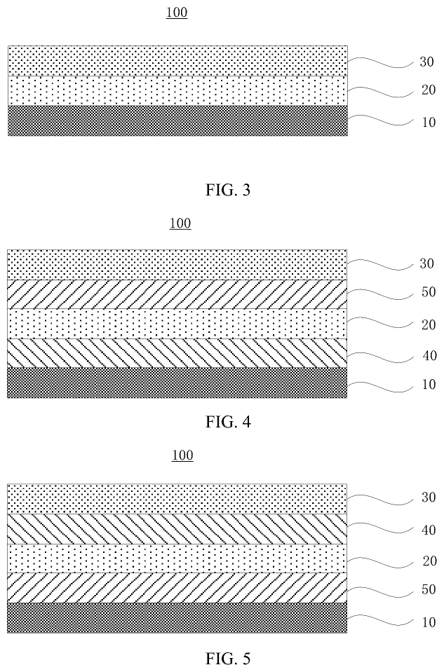

Referring to FIG. 3, embodiments of the present disclosure provide a light-emitting diode 100 including a bottom electrode 10, a light-emitting layer 20, and a top electrode 30 stacked sequentially. The light-emitting layer 20 is made of the quantum dot material, or a raw material for forming the light-emitting layer 20 is the composition.

In some embodiments, a method of forming the light-emitting layer 20 includes: using the composition as a raw material, disposing the composition on the bottom electrode 10 or the top electrode 30 by a solution method, and drying to obtain the light-emitting layer 20.

Moreover, the solution method may be a spin coating method, a printing method, an ink jet printing method, a blade coating method, a printing method, a dipping and pulling method, an immersion method, a spray coating method, a roll coating method, a casting method, a slit coating method, a strip coating method, or the like. The drying may be one or more of a heat drying, a temperature drying, and a reduced pressure drying.

In one embodiment, the bottom electrode 10 is an anode, and the top electrode 30 is a cathode. In yet another embodiment, the bottom electrode 10 is a cathode, and the top electrode 30 is an anode.

Referring to FIG. 4, in one embodiment, the light-emitting diode 100 further includes a hole transport layer 40 and an electron transport layer 50. The hole transport layer 40 is disposed between the bottom electrode 10 and the light-emitting layer 20, and the electron transport layer 50 is disposed between the light-emitting layer 20 and the top electrode 30. It can be understood that, in this embodiment, the bottom electrode 10 is an anode, and the top electrode 30 is a cathode.

Referring to FIG. 5, in yet another embodiment, the light-emitting diode 100 further includes a hole transport layer 40 and an electron transport layer 50. The electron transport layer 50 is disposed between the bottom electrode 10 and the light-emitting layer 20, and the hole transport layer 40 is disposed between the light-emitting layer 20 and the top electrode 30. It can be understood that, in this case, the bottom electrode 10 is a cathode, and the top electrode 30 is an anode.

The anode is an anode known in the art for use in light-emitting diode, for example, the anode may be selected from, but not limited to, a doped metal oxide electrode, a composite electrode, a graphene electrode, a carbon nanotube electrode, a metal elemental electrode, an alloy electrode, or the like. The doped metal oxide electrode may be made of a material selected from, but not limited to, one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), and aluminum-doped magnesium oxide (AMO). The composite electrode may be selected from, but not limited to, one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, and Mg/Ag. Herein, “/” represents a stacked structure, for example, AZO/Ag/AZO represents a composite electrode having a stacked structure in which an AZO layer, an Ag layer, and an AZO layer are stacked in this order.

The cathode may be made of a material selected from, but not limited to, one or more of Ag, Mg, Al, Au, Pt, Ca, and Ba.

A material of the hole transport layer 40 may be a material known in the art for use in hole transport layers, for example, the material of the hole transport layer 40 may be selected from, but not limited to, poly [bis(4-phenyl) (2,4,6-trimethylphenyl)amine](PTAA), 2,2′,7,7′-tetrakis [N, N-bis(4-methoxyphenyl)amino]-9,9′-spirobifluorene (spiro-omeTAD), 4,4′-cyclohexylbis [N,N-bis(4-methylphenyl) aniline](TAPC), N,N′-bis(1-neyl)-N,N′-bis(4-methylphenyl) aniline) (NPB), 4,4′-bis(N-carbazole)-1,1′-biphenyl (CBP), poly [(9,9-dioctylfluorenyl-2,7-diyl)-co-(4,4′-(N-(p-butylphenyl))diphenylamine)](TFB), poly(9-vinylcarbazole) (PVK), polytriphenylamine (Poly-TPD), and 4,4′, 4″-tris(carbazol-9-yl)triphenylamine (TCTA).

A material of the electron transport layer 50 is the material known in the art for electron transport layers, for example, material of the electron transport layer 50 may be selected from, but not limited to, one or more of a metal oxide, a doped metal oxide, a Group 2-6 semiconductor material, a Group 3-5 semiconductor material, and a Group 1-3-6 semiconductor material. Specifically, the metal oxide may be selected from, but not limited to, one or several kinds of ZnO, TiO₂, SnO₂, and Al₂O₃. The doped metal oxide may be selected from, but not limited to, one or more of ZnO, TiO₂, and SnO₂, and a doping element may be selected from, but not limited to, one or more of Al, Mg, Li, In, and Ga. For example, the doped metal oxide may be aluminum zinc oxide (AZO), lithium-doped zinc oxide (LZO), magnesium-doped zinc oxide (MO), or the like. The Group 2-6 semiconductor material may be selected from, but not limited to, one or more of ZnS, ZnSe, and CdS. The Group 3-5 semiconductor material may be selected from, but not limited to, one or more of InP and GaP. The Group 1-3-6 semiconductor material may be selected from, but not limited to, one or more of CuInS and CuGaS.

It can be understood that, the light-emitting diode 100 may further be equipped with some functional layers conventionally used for light-emitting diodes to improve the performance of the light-emitting diodes, such as a hole injection layer, an electron blocking layer, a hole blocking layer, an electron injection layer, an interface modification layer, and the like.

It can be understood that, materials of each layer of the light-emitting diode 100 can be adjusted according to light emitting requirements of the light-emitting diode 100.

It can be understood that, the light-emitting diode 100 may be a vertical light-emitting diode or an inverted light-emitting diode.

The light-emitting layer 20 of the light-emitting diode 100 includes the quantum dot material of the present disclosure, thereby having a high light-emitting efficiency, a long service life, and a low turn-on voltage.

The present disclosure is described in detail below by way of specific embodiments, the specific embodiments are only partial embodiments of the present disclosure and are not limited to the present disclosure.

### EXAMPLE 1

Quantum dot material preparation:
providing blue quantum dots CdZnSeS/ZnS, and dispersing the blue quantum dots in n-octane to obtain a quantum dot dispersion liquid having a concentration of 10 mg/mL;
adding 100 mL of phosphoric acid solution with a mass concentration of 5%, 20 mL of the quantum dot dispersion liquid, and 100 mg of trimethyl thiophosphate into a three-necked flask, and mixing evenly to obtain a mixed solution; blowing nitrogen at 80° C. for 30 minutes, and then heating to 200° C. and reacting for 1 hour while magnetically stirring, then cooling to room temperature, adding precipitating agent methanol, and collecting the precipitate and washing and drying to obtain a quantum dot material.

Light-emitting diode preparation:
providing an ITO anode with a thickness of 1 mm, wiping the surface of the ITO anode with a cotton swab dipped in a small amount of soapy water to remove impurities visible to the naked eye on the surface, then ultrasonically cleaning it with deionized water, acetone, ethanol and isopropyl alcohol for 15 minutes, and then blowing it dry with nitrogen for later use;
spin-coating a TFB material on the anode, and annealing at 100° C. for 10 minutes to obtain a hole transport layer 40 having a thickness of 30 nm;
dissolving the quantum dot material in n-octane to obtain a quantum dot material dispersion liquid with a concentration of 10 mg/mL, drawing 30 μL quantum dot material dispersion liquid with a pipette gun, and dropping onto the hole transport layer 40, spin coating at 2000 rpm for 30 seconds, and annealing at 100° C. for 5 minutes to obtain a light-emitting layer 20 having a thickness of 30 nm;
spin-coating 30 μL ethanol solution of ZnO on the light-emitting layer 20 at a rotation speed of 3000 rpm for 20 seconds, and annealing at 120° C. for 10 minutes to obtain an electron transport layer 50 having a thickness of 30 nm;
evaporating Mg on the electron transport layer 50 at a rate of 2 Å/s to obtain an Mg electrode layer having a thickness of 10 nm, and then evaporating Ag at a rate of 3 Å/s to obtain an Ag electrode layer having a thickness of 20 nm, thereby obtain an Mg/Ag composite cathode;
encapsulating with an ultraviolet curable adhesive to obtain a light emitting diode 100.

### EXAMPLE 2

Quantum dot material preparation:
providing blue quantum dots CdZnSeS/ZnS, and dispersing the blue quantum dots in n-octane to obtain a quantum dot dispersion liquid having a concentration of 30 mg/mL;
adding 100 mL of phosphoric acid solution with a mass concentration of 10%, 30 mL of the quantum dot dispersion liquid, and 200 mg of trimethyl thiophosphate into a three-necked flask, and mixing evenly to obtain a mixed solution; blowing nitrogen at 100° C. for 60 minutes, and then heating to 250° C. and reacting for 2 hours while magnetically stirring, then cooling to room temperature, adding precipitating agent methanol, and collecting the precipitate, and washing and drying to obtain a quantum dot material.

Light-emitting diode preparation:
providing an ITO anode with a thickness of 1 mm, wiping the surface of the ITO anode with a cotton swab dipped in a small amount of soapy water to remove impurities visible to the naked eye on the surface, then ultrasonically cleaning it with deionized water, acetone, ethanol and isopropyl alcohol for 15 minutes, and then blowing it dry with nitrogen for later use;
spin-coating a TFB material on the anode and annealing at 100° C. for 10 minutes to obtain a hole transport layer 40 having a thickness of 30 nm;
dissolving the quantum dot material in n-octane to obtain a quantum dot material dispersion liquid with a concentration of 30 mg/mL, drawing 60 μL quantum dot material dispersion liquid with a pipette gun, and dropping onto the hole transport layer 40, spin coating at 5000 rpm for 60 seconds, and annealing at 150° C. for 20 minutes to obtain a light-emitting layer having a thickness of 20 nm;
spin-coating 50 μL ethanol solution of ZnO on the light-emitting layer 20 at a rotation speed of 5000 rpm for 40 seconds, and annealing at 160° C. for 20 minutes to obtain an electron transport layer 50 having a thickness of 20 nm;
evaporating Mg on the electron transport layer 50 at a rate of 3 Å/s to obtain an Mg electrode layer having a thickness of 30 nm, and then evaporating Ag at a rate of 5 Å/s to obtain an Ag electrode layer having a thickness of 50 nm, thereby obtain an Mg/Ag composite cathode;
encapsulating with an ultraviolet curable adhesive to obtain a light emitting diode 100.

### EXAMPLE 3

Example 3 is basically the same as Example 1, the difference is that, the blue quantum dots of Example 3 are CdSeS/ZnS.

### EXAMPLE 4

Example 4 is basically the same as Example 1, the difference is that, the blue quantum dots of Example 4 are CdSeS.

### EXAMPLE 5

Example 5 is basically the same as Example 1, the difference is that, in Example 5, 30 mL of the quantum dot dispersion liquid is added into the three-necked flask.

### EXAMPLE 6

Example 6 is basically the same as Example 1, the difference is that, in Example 6, 200 mg of trimethyl thiophosphate is added into the three-necked flask.

### EXAMPLE 7

Example 7 is basically the same as Example 1, the difference is that, in Example 7, the concentration of the quantum dot dispersion liquid is 30 mg/mL.

### EXAMPLE 8

Example 8 is basically the same as Example 1, the difference is that, in Example 8, the concentration of the quantum dot dispersion liquid is 30 mg/mL, and 30 mL of the quantum dot dispersion liquid is added into the three-necked flask.

### EXAMPLE 9

Example 9 is basically the same as Example 1, the difference is that, in Example 9, the concentration of the quantum dot dispersion liquid is 30 mg/mL, 30 mL of the quantum dot dispersion liquid, and 200 mg of trimethyl thiophosphate are added into the three-necked flask.

### EXAMPLE 10

Example 10 is basically the same as Example 1, the difference is that, in Example 10, there is no phosphoric acid solution is added during the preparation of quantum dot material.

### EXAMPLE 11

Example 11 is basically the same as Example 1, the difference is that, in Example 11, during the preparation of quantum dot material, 100 mL of phosphoric acid solution with a mass concentration of 5% is replaced by 100 mL of nitric acid solution with a mass concentration of 5%.

### COMPARATIVE EXAMPLE

Comparative Example is basically the same as Example 1, the difference is that, a preparation method of the light-emitting layer of the Comparative Example includes:
dissolving blue quantum dots CdZnSeS/ZnS in n-octane to obtain a quantum dot material dispersion liquid with a concentration of 10 mg/mL, drawing 30 μL quantum dot material dispersion liquid with a pipette gun, and dropping onto the hole transport layer 40, spin coating at 2000 rpm for 30 seconds, and annealing at 100° C. for 5 minutes to obtain a light-emitting layer having a thickness of 30 nm.

In the Comparative Example, the quantum dot material is the blue quantum dots CdZnSeS/ZnS, and the quantum dot material does not contain trimethyl thiophosphate.

The maximum external quantum efficiency (EQEₘₐₓ), the service life T95, and the service life T95@1knit of the light-emitting diodes of Examples 1-11 and Comparative Example are tested respectively. Moreover, T95 refers to the time required for the initial brightness of the device to attenuate to 95%. T95@1knit refers to the time it takes for the initial brightness of the device to decay to 95% and convert to the aging time at 1000 nit. The test results are shown in Table 1.

A test method of the maximum external quantum efficiency EQEₘₐₓ is: the efficiency test system built by LabView control QE PRO spectrometer, Keithley 2400, and Keithley 6485 is used for test, wherein a driving current is 2 mA.

Life T95 and T95@1knit are tested by a 128-channel life test system customized by Guangzhou New Vision Company. The system architecture is driving QLED with constant voltage and constant current source to test the change of voltage or current. A photodiode detector and the test system test the change of brightness (photocurrent) variation of QLED. A brightness meter tests and calibrates the brightness (photocurrent) of QLED, thereby to obtain the time it takes for the initial brightness of the light-emitting diode to decay to 95%. Moreover, the driving current is 2 mA.

TABLE 1

| | EQEₘₐₓ | T95 | T95@1knit | turn-on voltage |
|---|---|---|---|---|
| | (%) | (h) | (h) | (V) |
| Example 1 | 23 | 64 | 2400 | 1.5 |
| Example 2 | 24 | 66 | 2500 | 1.4 |
| Example 3 | 22 | 64 | 2350 | 1.5 |
| Example 4 | 20 | 59 | 2100 | 1.7 |
| Example 5 | 23 | 63 | 2250 | 1.6 |
| Example 6 | 22 | 62 | 2200 | 1.6 |
| Example 7 | 23 | 63 | 2350 | 1.5 |
| Example 8 | 21 | 61 | 2200 | 1.6 |
| Example 9 | 22 | 61 | 2300 | 1.5 |
| Example 10 | 20 | 58 | 2000 | 1.6 |
| Example 11 | 21 | 60 | 2150 | 1.6 |
| Comparative Example | 16 | 47 | 1800 | 1.9 |

It can be seen from Table 1 that:

The light-emitting diodes of Examples 1-11 have higher light-emitting efficiency, longer service life, and lower turn-on voltage than the light-emitting diodes of Comparative Example. It can be seen that, the quantum dot material of the present disclosure can effectively improve the light-emitting efficiency of the light-emitting diode, prolong the service life of the light-emitting diode, and reduce the turn-on voltage of the light-emitting diode.

The light-emitting diode of Example 1 and Example 11 have higher light-emitting efficiency and longer service life than the light-emitting diode of Example 10. It can be seen that, the addition of acid in the preparation process of the quantum dot material can effectively improve the performance of the quantum dot material, thereby improve the light-emitting efficiency and service life of the light-emitting diode made of the quantum dot material.

The light-emitting diode of Example 1 has higher light-emitting efficiency, longer service life, and lower turn-on voltage than the light-emitting diode of Example 11. It can be seen that, the addition of phosphoric acid in the preparation process of the quantum dot material can more effectively improve the performance of the quantum dot material, thereby improving the light-emitting efficiency and the service life of the light-emitting diode made of the quantum dot material. A reason may be that, when phosphoric acid is used, the phosphate radical in the phosphoric acid can also perform P-type doping on the quantum dots during the reaction process between the quantum dots and the trimethyl thiophosphate, which can further reduce the Fermi level of the quantum dot, thereby causing the quantum dot material to have a a lower Fermi level.

The quantum dot material and preparation method therefor, and the light-emitting diode according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

1. A quantum dot material, comprising:
quantum dots; and
ligands each of which is bonded to a surface of one of the quantum dots, and each of the ligands having a structural formula as following: 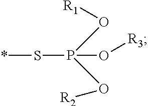
wherein R₁, R₂, and R₃ are independently selected from a substituted or unsubstituted linear alkyl group having 1 to 20 carbon atoms, or a substituted or unsubstituted branched alkyl group having 3 to 20 carbon atoms;
* represents an attachment site to which the quantum dots bind.

2. The quantum dot material according to claim 1, wherein the quantum dot material is comprised of the quantum dots and the ligands each of which is bonded to the surface of one of the quantum dot.

3. The quantum dot material according to claim 1, wherein R₁, R₂, and R₃ are all selected from methyl.

4. The quantum dot material according to claim 1, wherein in the quantum dot material, a mass ratio of the quantum dots to the ligands is (0.5˜2):1.

5. The quantum dot material according to claim 1, wherein an emission wavelength of each of the quantum dots ranges from 465 nm to 480 nm.

6. The quantum dot material according to claim 1, wherein the quantum dots are selected from single structure quantum dots, and the single structure quantum dots are selected from one or more of CdZnSeS, CdS, ZnS, ZnSeS, CdSeS, CdZnS, ZnTeS, CdTeS, ZnCdTeS, CuInS₂, and AgInS₂.

7. The quantum dot material according to claim 1, wherein the quantum dots are selected from core-shell structured quantum dots, and a material of an outermost shell layer of each of the quantum dots is selected from one or more of CdZnSeS, CdS, ZnS, ZnSeS, CdSeS, CdZnS, ZnTeS, CdTeS, ZnCdTeS, CuInS₂, and AgInS₂; a material of a quantum dot core of each of the quantum dots and materials of shell layers of each of the quantum dots except the outermost shell layer are independently selected from one or more of a Group II-VI compound, a Group III-V compound, and a Group I-III-VI compound, the Group II-VI compound is selected from one or more of CdSe, CdS, CdTe, ZnSe, ZnS, CdTe, ZnTe, CdZnS, ZnCdSe, CdZnTe, ZnSeS, ZnSeTe, ZnTeS, CdSeS, CdSeTe, CdTeS, ZnCdSeTe, and ZnCdSTe; the Group III-V compound is selected from one or more of InP, InAs, GaP, GaAs, GaSb, AlN, AlP, InAsP, InNP, InNSb, GaAlNP, and InAlNP; the Group I-II-VI compound is selected from one or more of CuInS₂, CuInSe₂, and AgInS₂.

8. The quantum dot material according to claim 1, wherein the quantum dots are selected from one or more of a blue core-shell quantum dot CdZnSeS/ZnS or a blue core-shell quantum dot CdSeS/ZnS.

9. A preparation method for a quantum dot material, comprising following steps:
dispersing quantum dots in a dispersant to obtain a quantum dot dispersion liquid; and
mixing compounds A to the quantum dot dispersion liquid, and heating to obtain a quantum dot material;
wherein each of the compounds A has a structural formula as following: 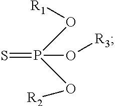
wherein R₁, R₂, and R₃ are independently selected from a substituted or unsubstituted linear alkyl group having 1 to 20 carbon atoms, or a substituted or unsubstituted branched alkyl group having 3 to 20 carbon atoms.

10. The method according to claim 9, wherein the quantum dot material comprises quantum dots and ligands each of which is bonded to a surface of one of the quantum dots, each of the ligands has a structural formula as following: 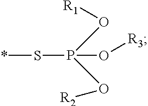
wherein * represents an attachment site to which the quantum dots bind.

11. The method according to claim 9, wherein a concentration of the quantum dot dispersion liquid ranges from 10 mg/mL to 30 mg/mL.

12. The method according to claim 9, wherein a mass ratio of the compounds A to the quantum dots is (2˜9):(1˜2).

13. The method according to claim 9, wherein the heating comprises: blowing an inert gas at a first temperature for a first time, and then reacting at a second temperature for a second time.

14. The method according to claim 13, wherein the first temperature ranges from 80° C. to 100° C., and the first time ranges from 30 minutes to 60 minutes.

15. The method according to claim 13, wherein the second temperature ranges from 200° C. to 250° C., and the second time ranges from 1 hours to 2 hours.

16. The method according to claim 9, wherein before the heating, the method further comprises: mixing an acid to the quantum dot dispersion liquid to adjust the pH of the solution system to 6˜7.

17. The method according to claim 16, wherein the acid is selected from one or more of phosphoric acid, nitric acid, and sulfuric acid.

18. A light-emitting diode, comprising:
a bottom electrode, a light-emitting layer, and a top electrode stacked sequentially;
wherein the light-emitting layer is made of a quantum dot material according to claim 1.

19. The light-emitting diode of claim 18, wherein,
the anode is selected from a doped metal oxide electrode, a composite electrode, a graphene electrode, a carbon nanotube electrode, a metal elemental electrode, or an alloy electrode, the doped metal oxide electrode is made of a material selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS;
the cathode is made of a material selected from one or more of Ag, Mg, Al, Au, Pt, Ca, and Ba.
